(19) United States
(12) Patent Application Publication
(10) Pub. No.: US 2021/0242015 A1
(43) Pub. Date: Aug. 5, 2021

(54) SUBSTRATE PROCESSING APPARATUS AND SUBSTRATE CLEANING METHOD

(71) Applicant: EBARA CORPORATION, Tokyo (JP)

(72) Inventor: Tomoatsu Ishibashi, Tokyo (JP)

(21) Appl. No.: 17/049,001

(22) PCT Filed: Apr. 6, 2020
(86) PCT No.: PCT/JP2020/015460

§ 371 Date: Oct. 19, 2020

(30) Foreign Application Priority Data
Apr. 9, 2019 (JP) 2019-074012

(51) Int. Cl. H01L 21/02; H01L 21/67; B08B 1/00; B08B 3/08

(52) U.S. Cl. CPC H01L 21/02087; B08B 3/08; B08B 1/001; H01L 21/67046

(57) ABSTRACT

Provided is a substrate processing apparatus including: a first cleaning member configured to clean a substrate by a contact face on which a skin layer is provided; and a second cleaning member configured to clean the substrate after cleaned by the first cleaning member, by a contact face on which a skin layer is not provided.

### TECHNICAL FIELD

The present inventions relate to a substrate processing apparatus and a substrate cleaning method for cleaning a substrate with a cleaning member.

### BACKGROUND

Patent literature 1 discloses a cleaning member having a skin layer on a contact face to a substrate and a cleaning member not having a skin layer on a contact face to the substrate. However, it is unclear from Patent literature 1 how to selectively use them properly for effective substrate cleaning.

### CITATION LIST

### Patent Literatures

Patent Literature 1: JP2018-56385A

Patent Literature 2: WO2016/67563A

Patent Literature 3: JP2017-191827A

### SUMMARY OF INVENTIONS

### Problem to be Solved by Inventions

The present inventions is conceived taking the above problems into consideration, the problem of the present invention is to provide a substrate processing apparatus and a substrate cleaning method which have a high cleaning ability.

### Solution to Problem

According to one embodiment of the present invention, provided is a substrate processing apparatus including: a first cleaning member configured to clean a substrate by a contact face on which a skin layer is provided; and a second cleaning member configured to clean the substrate after cleaned by the first cleaning member, by a contact face on which a skin layer is not provided.

The substrate processing apparatus may include a cleaning liquid supplying unit configured to supply a cleaning liquid in which gas is dissolved to an inside of the second cleaning member, wherein the cleaning liquid supplied to the inside of the second cleaning member may reaches the substrate from a surface of the second cleaning member.

The cleaning liquid supplying unit may include: a supplying line connected to the inside of the second cleaning member; a gas dissolver configured to dissolve the gas to the cleaning liquid; and a filter provided between the gas dissolver and the second cleaning member on the supplying line.

The cleaning liquid supplying unit may include: a supplying line connected to the inside of the second cleaning member; a bubble containing cleaning liquid generator configured to generate bubble-dissolved cleaning liquid; and a filter provided between the bubble containing cleaning liquid generator and the second cleaning member on the supplying line.

It is preferable that the cleaning liquid reaching the substrate contains a bubble.

It is preferable that the cleaning liquid reaching the substrate contains the bubble whose diameter is less than 100 nm.

It is preferable that the cleaning liquid reaching the substrate does not contain the bubble whose diameter is equal to or more than 100 nm.

According to another embodiment of the present invention, provided is a substrate cleaning method including: a first cleaning step configured to clean a substrate by a contact face of a first cleaning member, a skin layer being provided on the contact face; and a second cleaning step after the first cleaning step configured to clean the substrate by a contact face of a second cleaning member, a skin layer not being provided on the contact face.

It is preferable that the second cleaning step includes: supplying cleaning liquid containing a bubble whose diameter is less than 100 nm to an inside of the second cleaning member, and performing cleaning by the second cleaning member while causing the cleaning liquid to reach the substrate from a surface of the second cleaning member.

It is preferable that the substrate cleaning method further includes a step configured to, before the second cleaning member is firstly used, supply a bubble whose diameter is less than 100 nm to an inside of the second cleaning member to discharge the cleaning liquid from a surface of the second cleaning member.

It is preferable that the substrate cleaning method further includes a step configured to, after completing one substrate and before starting cleaning another substrate, supply a bubble whose diameter is less than 100 nm to an inside of the second cleaning member to discharge the cleaning liquid from a surface of the second cleaning member.

### Effect of Invention

Substrate cleaning ability improves.

### BRIEF DESCRIPTION OF DRAWINGS

FIG. 1 is a schematic top view of a substrate processing apparatus according to one embodiment.

FIG. 2 is a perspective view showing a schematic configuration of the substrate cleaning device 4a.

FIG. 3A is a side view of the cleaning member 12a in the longitudinal direction.

FIG. 3B is a modified example of cleaning members 12a and 12b.

FIG. 3C is another modified example of cleaning members 12a and 12b.

FIG. 4 is a side view of the cleaning member 12b in the longitudinal direction.

FIG. 5 is a process diagram showing an example of the processing operation in the substrate processing apparatus.

FIG. 6A is a drawing explaining cleaning liquids A to C used in the experiment.

FIG. 6B is a drawing showing results of cleaning experiments using pure water and chemical liquid of cleaning liquids A to C.

FIG. 7 is a diagram showing a schematic configuration of a cleaning liquid supplying unit 30 that supplies the cleaning liquid to the inside of the cleaning member 12b.

FIGS. 8A and 8B are schematic diagrams showing how the cleaning liquid reaches the substrate S from the cleaning member 12b.

FIG. 9 is a diagram showing a schematic configuration of a cleaning liquid supplying unit 30′ which is a modified example of FIG. 7.

FIG. 10 is a perspective view showing a schematic configuration of another substrate cleaning device 4A.

### Embodiments to Employ an Invention

Hereinafter, embodiments according to the present invention will be described with reference to drawings.

### First Embodiment

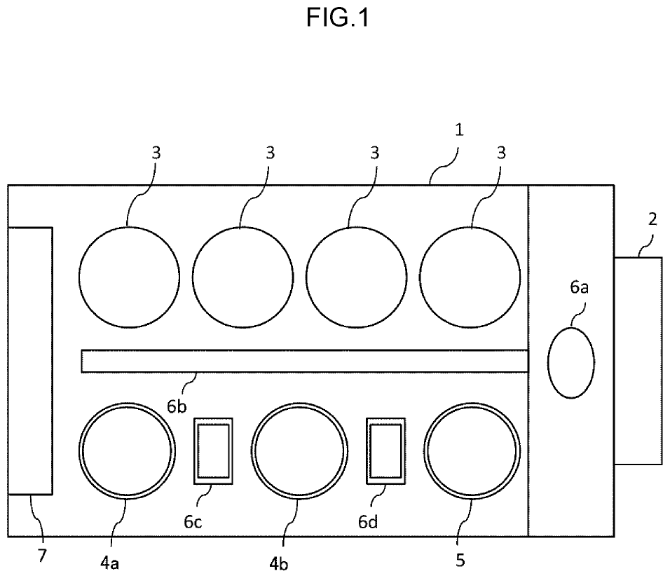

FIG. 1 is a schematic top view of a substrate processing apparatus according to one embodiment. This substrate processing apparatus processes various substrates such as a semiconductor wafer having a diameter of 300 mm or 450 mm, a flat panel, an image sensor such as a CMOS (Complementary Metal Oxide Semiconductor) or a CCD (Charge Coupled Device), a magnetic film of MRAM (Magnetoresistive Random Access Memory) in the manufacturing process. The shape of the substrate is not limited to a circular shape, and may be a rectangular shape (square shape) or polygonal shape.

The substrate processing apparatus includes a substantially rectangular housing 1, a load port 2 on which a substrate cassette for mounting a large number of substrates is placed, one or more (4 in the embodiment shown in FIG. 1) substrate polishing devices 3, a plurality of (two in the embodiment shown in FIG. 1) substrate cleaning devices 4a and 4b, a substrate drying device 5, transfer mechanisms 6a to 6d, and control unit 7.

The load port 2 is located adjacent to the housing 1. The load port 2 can be equipped with an open cassette, SMIF (Standard Mechanical Interface) port, or FOUP (Front Opening Unified Pod). The SMIF port and the FOUP are closed containers that can store the substrate cassette inside and cover it with a partition wall to keep the environment independent of the external space.

The substrate polishing devices 3 for polishing the substrate, the substrate cleaning device 4a for cleaning the substrate after polishing, the substrate cleaning device 4b for further cleaning the substrate cleaned by the substrate cleaning device 4a, the substrate drying device 5 for drying the substrate after cleaning are housed in the housing 1. The substrate polishing devices 3 are arranged along the longitudinal direction of the substrate processing apparatus, and the substrate cleaning devices 4a, 4b and the substrate drying device 5 are also arranged along the longitudinal direction of the substrate processing apparatus.

Further, the substrate cleaning devices 4a, 4b and the substrate drying device 5 each may have a substantially rectangular casing (not shown), on which an opening/closing portion is provided which can be opened and closed by a shutter mechanism, so that a target substrate to be processed can be taken in and out through the opening/closing portion. Alternatively, as a modified example, the substrate cleaning devices 4a and 4b and the substrate drying device 5 are integrated so that the substrate cleaning process and the substrate drying process are performed continuously in one unit

The transport mechanism 6a is arranged in an area surrounded by the load port 2, the substrate polishing device 3 located at the side of the load port 2 and the substrate drying device 5. The transport mechanism 6b is arranged parallel to the substrate polishing device 3, and the substrate cleaning devices 4a, 4b and the substrate drying device 5. The transport mechanism 6a receives the substrate before polished from the load port 2 and transfers it to the transport mechanism 6b, and receives the substrate after dried taken out from the substrate drying device 5.

The transfer mechanism 6c for transferring the substrate between the substrate cleaning devices 4a and 4b is arranged therebetween. The transport mechanism 6d for transferring the substrate between the substrate cleaning device 4b and the substrate drying device 5 is arranged therebetween.

Furthermore, a controller 7 that controls the movement of each device of the substrate processing apparatus is arranged inside the housing 1. In the present embodiment, an explanation will be performed using an embodiment in which the controller 7 is arranged inside the housing 1. However, the present invention is not limited to this, and the controller 7 may be arranged outside the housing 1. For example, the controller 7 can be configured to control the operation of spindles 11 holding and rotating the substrate, injection start and finish timing of nozzles which injects cleaning liquid toward the substrate, or up and down movement and swiveling movement in the vertical plane of the nozzle.

Note that the controller 7 may include a memory that stores a predetermined program, a CPU (Central Processing Unit) that executes the program in the memory, and a control module realized by the CPU executing the program. The controller 7 is configured to be communicable with a host controller (not shown) that integrally controls the substrate processing apparatus and other related devices, and can exchange data with a database that the host controller has. Here, the storage medium that constitutes the memory stores various programs such as various setting data and processing programs. As the storage medium , well-known items such as a computer-readable memory such as ROM and RAM and a disk-shaped storage medium such as a hard disk, CD-ROM, DVD-ROM and a flexible disk can be used.

According to the present embodiment, the substrate processing apparatus includes two kind of the substrate cleaning devices 4a and 4b. Firstly, the substrate cleaning device 4a will be explained.

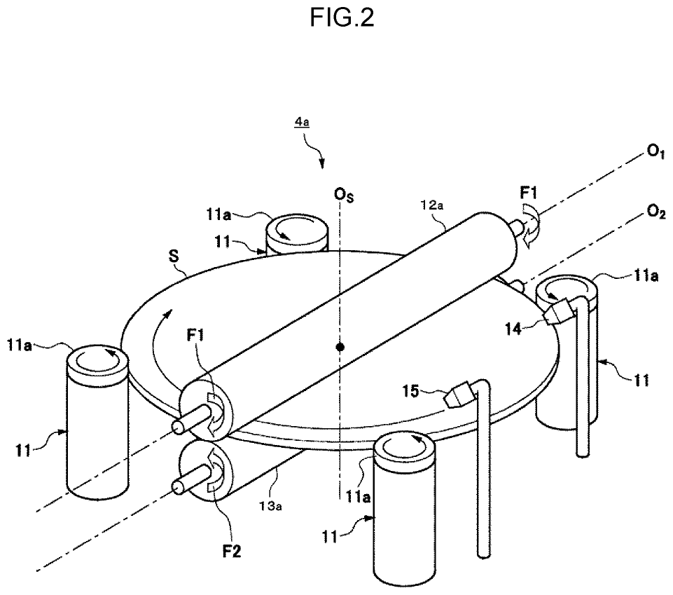

FIG. 2 is a perspective view showing a schematic configuration of the substrate cleaning device 4a. The substrate cleaning device 4a includes a plurality of spindles 11 (four spindles in FIG. 2), a cleaning member 12a and a roll-type cleaning member 13a, the spindles 11 being movable in the horizontal direction and supporting a peripheral portion of the substrate S to horizontally rotate it, the cleaning member 12a cleaning the upper surface of substrate S, and the cleaning member 13a cleaning the lower surface of substrate S.

The spindles 11 support the peripheral edges of the substrate S and rotate it in a horizontal plane. More specifically, the spindles 11 locate and press inward the peripheral edges of the substrate S in grip groove formed on the outer peripheral surface of the comma 11a provided on the upper portion of the spindle 11, and at least one of the spindles 11 is rotated (self-rotated) , by which the substrate S rotates. Here, since the coma grips the substrate, the “coma” can be paraphrased as a “grip part”. Also, the “spindle” can be paraphrased as a “roller.”

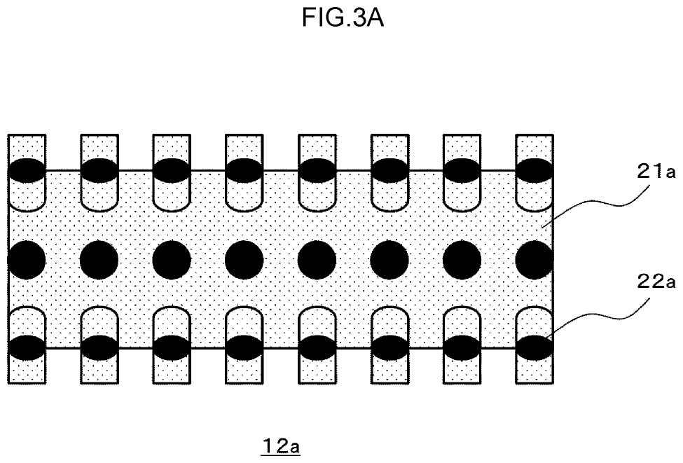

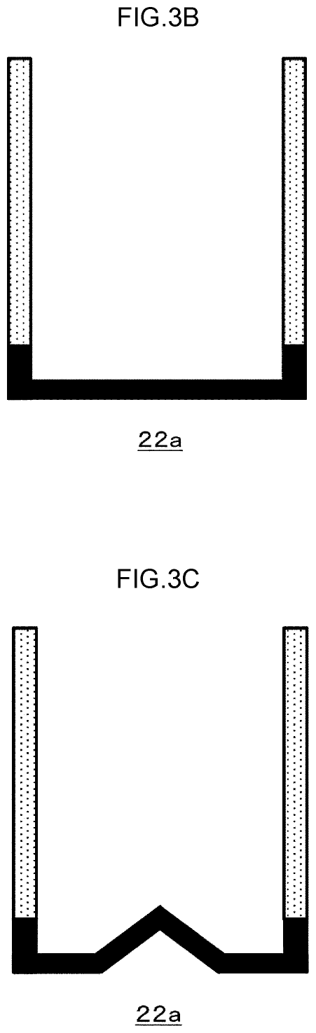

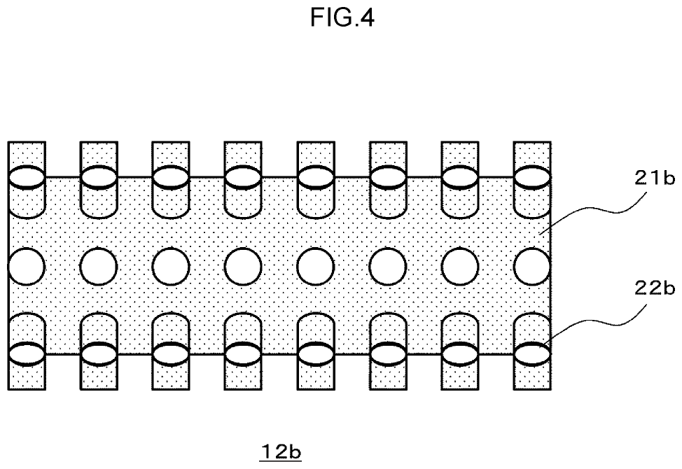

The cleaning members 12a, 13a are sponge-like or cotton-like porous members. The material is typically PVA (Polyvinyl Alcohol) and may be Teflon material, polyurethane material, PP (Polypropylene), etc. The cleaning members 12a, 13a have a cylindrical shape extending in a long shape. And, the cleaning members 12a, 13a are rotatably supported by a roll holder (not shown) and can move up and down with respect to the front surface and the back surface of the substrate S. The cleaning members 12a, 13a rotate as shown by arrows F1 and F2 by a drive mechanism (rotation drive means) which is not shown. The structure of the cleaning members 12a and 13a will be described later with reference to FIGS. 3A and 3B.

The lengths of the cleaning members 12a, 13a are set to slightly longer than the diameter of the substrate S. The cleaning members 12a, 13a have their central axes (rotation axes) O1, O2 that are substantially normal to a central axes of the substrate S (that is, the center of rotation) (parallel to the surface of the substrate S), and arranged so that they extends over the entire length of the diameter of the substrate S. Accordingly, both of the entire front and back surfaces of the substrate S are cleaned at the same time. Note that, though the cleaning members 12a, 13a are parallel each other with the substrate S in between in FIG. 2, they may be nonparallel.

The two cleaning liquid supply nozzles 14, 15 are arranged above the substrate S which is supported and rotated by the spindle 11, and supplies the cleaning liquid to the surface of the substrate S. The cleaning liquid supply nozzle 14 supplies rinse liquid (for example, ultrapure liquid) on the surface of the substrate S, and the cleaning liquid supply nozzle 15 supplies chemical liquid to the surface of the substrate S.

The substrate cleaning device 4a operates as follows. By rotating (self-rotating) the coma 11a by positioning and pressing inward the peripheral edge of the substrate S inside the fitting groove formed on the outer peripheral side of the coma 11a provided on the upper part of the spindle 11 to rotate the substrate S horizontally. In this example, two of the four comas 11a give a rotational force to the substrate S, and the other two comas 11a act as bearing to receive the rotation of the substrate S. Note that, all the comas 11a may be connected to the drive mechanism to give a rotational force to the substrate S.

In this way, under a state where the substrate S is rotated horizontally, while supplying the rinse liquid and the chemical liquid from the cleaning liquid supply nozzles 14, 15 to the surface of the substrate S, the cleaning member 12a is rotated and lowered by the vertical drive mechanism (not shown) to cause the cleaning member 12a contact with the front surface of the rotating substrate S and the cleaning member 13a is rotated and raised by the vertical drive mechanism (not shown) to cause the cleaning member 13a contact with the back surface of the rotating substrate S.

Accordingly, under the presence of the cleaning liquid (rinse liquid and chemical liquid) , the front and back surfaces of the substrate S are scrub-cleaned by the cleaning members 12a, 13a, respectively. The vertical drive mechanisms of the cleaning members 12a, 13a may move them up and down in a direction vertical to the surface of the substrate S, perform pivot-operation using a certain point as a start point, or may operate combining these operations.

FIG. 3A is a side view of the cleaning member 12a in the longitudinal direction. The cleaning member 12a has a cylindrical roll body 21a and a plurality of nodule portions 22a protruding outward from the outer peripheral surface thereof in a cylindrical shape. The cleaning member 12a included in the substrate cleaning device 4a has a skin layer at least at the tip of the nodule portion 22a, in other words, at the surface that comes into contact with the substrate S during cleaning. The other surface may or may not have a skin layer.

Note that, in FIG. 3A, the black-painted part indicates the skin layer. The part with spots indicates that the skin layer may or may not be provided. The same applies to FIGS. 3B and 3C described later. The cleaning member 13a has the same structure as the cleaning member 12a.

Supplement explanation will be performed about the skin layer. When molding resin such as PVA to produce cleaning members 12a, 13a, a surface layer part that is in contact with the mold during molding and a lower layer part inside is formed. The surface layer part is the skin layer. The skin layer has a thickness of about 1 to 10 μm (micro meter) and covers the surface in a uniformly covered state. The skin layer may partially have holes of several μm to several tens of μm. Therefore, the skin layer is a structurally hard layer compared to the surface of the sponge structure. On the other hand, the lower layer has a sponge structure with a large pore diameter of 10 μm to several hundreds of μm, which is a soft layer.

The inventors compared the particle removal performances with and without the skin layer, and found that with the skin layer, it is effective for relatively large particles and particles with strong adhesiveness, and that without the skin layer, it is effective for relatively small particles by experiments. That is, it is considered that giving a large physical force from a hard skin layer is effective for large particles and particles with strong adhesiveness while repeated physical force from a large number of small concave and convex portions of the sponge structure at a lower layer is effective for the small particle. Therefore, in order to remove small particles under large particles or between large particles, removing large particles firstly is more efficient.

The cleaning members 12a, 13a of the substrate cleaning device 4a are provided with the hard skin layers on the nodule portions 22a which is a contact surface with the substrate S. Therefore, the cleaning members 12a, 13a are able to efficiently remove relatively large particles attached to and adhered to the substrate S.

It should be noted that it is enough that at a part of a contact face to the substrate S is provided with a skin layer. FIGS. 3B and 3C exemplify the shape of the nodules 22a, and the thick lines show the skin layer. As shown in the side view in FIG. 3B, the nodule portion 22a may have a cylindrical shape with a flat tip surface, and the tip surface and a part of the side surface (tip surface side) may be a skin layer. As shown in the side view in FIG. 3C, the nodule portion 22a has a substantially cylindrical shape with a groove formed on the tip surface, and the tip surface, the groove surface and part of the side surface (tip surface side) are the skin layer. According to the embodiment of FIG. 3C, the edge of the groove improves the cleaning effect.

Next, the substrate cleaning device 4b will be explained. Compared the substrate cleaning device 4b to the substrate cleaning device 4b, the cleaning members 12b, 13b included in the substrate cleaning device 4b are different from the cleaning members 12a, 13a included in the substrate cleaning device 4a, and other structures are common. Therefore, only the cleaning member 12b, 13b will be explained.

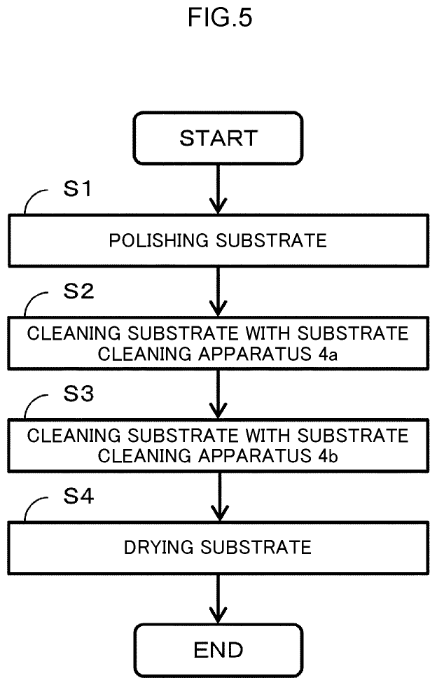

FIG. 4 is a side view of the cleaning member 12b in the longitudinal direction. The cleaning member 12b has a cylindrical roll body 21b and a plurality of nodule portions 22b protruding outward from its outer peripheral surface in a cylindrical shape. Skin layer is not provided (removed) on at least a tip of the nodules 22b, namely a surface contacting to the substrate S while cleaning , and the lower layer is exposed. The other surface may or may not have a skin layer. Note that, in FIG. 4, the white parts indicate that the skin layer is not provided. The spotted-part indicates that the skin layer may or may not be provided. The cleaning member 13b has the same structure as the cleaning member 12b.

The cleaning members 12b, 13b of the substrate cleaning device 4b are not provided with a hard skin layer on the contact surface with the substrate S. Therefore, the cleaning members 12b, 13b are able to remove relatively small particles adhering to substrate S efficiently by rubbing against the substrate S with minute contact sides or corners that form a mesh.

The present inventors found the difference of cleaning characteristics due to presence/non-presence of the skin layer described above, and selectively use as described below.

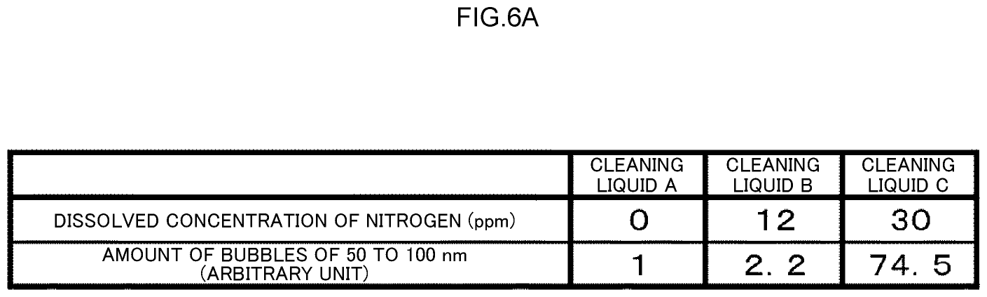

FIG. 5 is a process diagram showing an example of the processing operation in the substrate processing apparatus. First, the substrate S put into the substrate processing apparatus of FIG. 1 is carried into the substrate polishing device 3 by the transfer mechanisms 6a and 6b and polished. (Step S1). Polishing debris (particles) of various sizes adheres to the surface of the substrate S after polishing. Also, the slurry and the chemical solution used in the substrate polishing device 3 are mixed and aggregated in various sizes, which adheres to the substrate S.

The polished substrate S is carried into the substrate cleaning device 4a by the transfer mechanism 6b in FIG. 1. Then, the cleaning member 12a, 13a of the substrate cleaning device 4a cleans the substrate S (step S2 in FIG. 5). Since the skin layers are formed on the contact surface of the cleaning members 12a, 13a contacting with the substrate S, large particles adhering to the substrate S are mainly removed. On the other hand, small particles adhering to the substrate S may remain without being removed.

Subsequently, the substrate S cleaned by the substrate cleaning device 4a is carried into the substrate cleaning device 4b by the transfer mechanism 6c of FIG. 1. Then, the cleaning members 12b, 13b of the substrate cleaning device 4b clean the substrate S (Step S3 in FIG. 5). Since no skin layer is formed on the contact surfaces of cleaning members 12b, 13b contacting with substrate S, small particles that could not be completely removed by substrate cleaning device 4a are also removed.

Note that, it is preferable that after the substrate S is cleaned by the substrate cleaning device 4b, the substrate S is not cleaned by the substrate cleaning device 4a.

Then, the substrate S cleaned by the substrate cleaning device 4b is put into the substrate drying device 5 by the transfer mechanism 6d of FIG. 1, and the substrate S is dried (Step S4). After that, the substrate S is carried out from the substrate processing apparatus.

As stated, according to the first embodiment, firstly the substrate S is cleaned by the cleaning members 12a and 13a having the skin layer on the contacting surface to the substrate S, thereby removing mainly large particles and particles adhered to the substrate S (rough cleaning). After that, the substrate S is cleaned by the cleaning members 12b and 13b not having the skin layer on the contacting surface to the substrate S, thereby removing mainly small particles (finishing cleaning). Since such two step cleaning is performed, both of large particles and small particles can be effectively removed.

Note that, in the present embodiment, the substrate processing apparatus includes two substrate cleaning devices 4a, 4b, and the former includes the cleaning members 12a, 13a whose contacting surface to the substrate S has the skin layer formed thereon, and the latter includes the cleaning members 12b, 13b whose contacting surface to the substrate S does not have the skin layer formed thereon. However, one substrate cleaning device includes a cleaning member with the skin layer on the contacting surface and a cleaning member without the skin layer on the contacting surface. In this case, firstly cleaning by the cleaning member with the skin layer on the contacting surface to the substrate S is performed, and after that, cleaning by the cleaning member without the skin layer is performed.

### Second Embodiment

In order to remove small particles, it is effective to perform cleaning with cleaning liquid including small bubble (whose diameter is equal to or less than about 100 nm, hereinafter called “nano bubble”). This is because, by interposing nano bubbles between the cleaning member and the particle to be removed, the nano bubbles functions as air slurry, thereby improving the efficiency. In addition, by the nano bubble being adsorbed to the removed particles, it is also possible to prevent the removed particles from reattaching to the substrate and from attaching to the cleaning member. Hereinafter, this is shown in the following experiment.

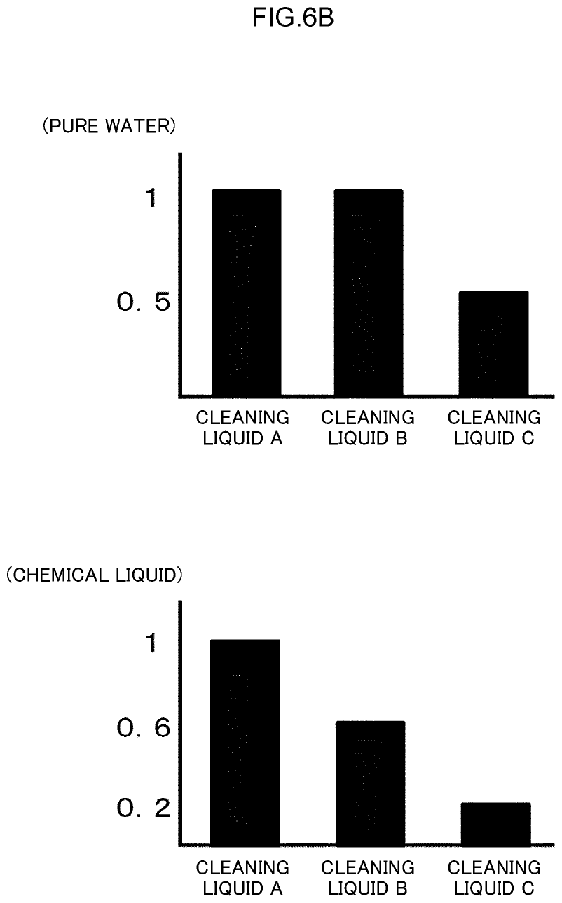

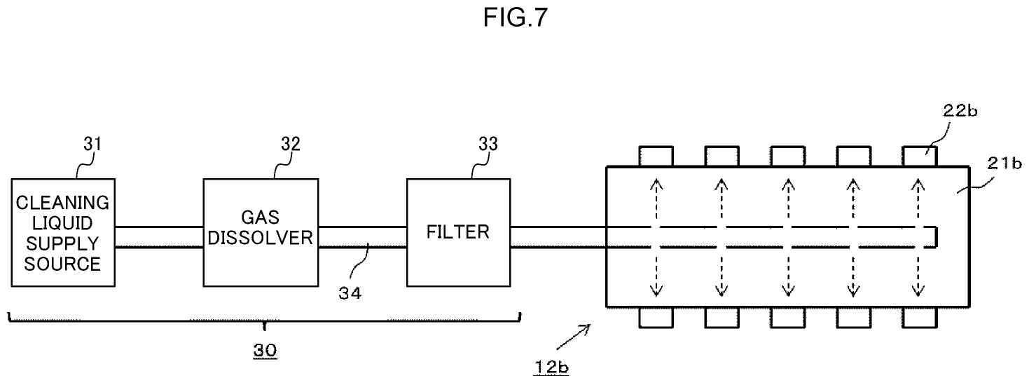

FIG. 6A shows cleaning liquids A to C used in the experiment. As the cleaning liquid A, pure water and chemical liquid with almost no gas dissolved were prepared. As the cleaning liquid B, pure water and chemical liquid with dissolved gas (nitrogen) concentration of 12 ppm (less than saturation), which is the same level as the cleaning liquid supplied in the semiconductor factory, were prepared. The number of bubbles whose diameter is 50-100 nm existing in the cleaning liquid B is about 2.2 times as the number of those bubbles existing in the cleaning liquid A. As cleaning liquid C, pure water and chemical liquid with dissolved gas (nitrogen) concentration of 30 ppm (supersaturated) were prepared. The number of bubbles whose diameter is 50-100 nm existing in the cleaning liquid C is about 74.5 times as the number of those bubbles existing in the cleaning liquid A.

FIG. 6B shows results of cleaning experiments using pure water and chemical liquid of cleaning liquids A to C, where the vertical axis is the relative amount of remaining particles. For pure water, comparing to a case where the cleaning liquids A and B were used, the amount of remaining particles was reduced to about 50% by using the cleaning liquid C. For chemical liquid, comparing to a case where the cleaning liquid A was used, the amount of remaining particles was reduced to 60% by using the cleaning liquid B and was reduced to 20% by using the cleaning liquid C.

In this way, the particles can be efficiently removed by using the cleaning liquid containing a large amount of nano bubbles. In the above-described first embodiment, while supplying cleaning liquid including nano bubbles from the cleaning liquid supply nozzle 14 and/or the cleaning liquid supply nozzle 15 to the surface of the substrate S, the surface of the substrate S may be cleaned. Further, according to a second embodiment described below, substrate cleaning is performed while supplying cleaning liquid containing nano bubbles from the inside of the cleaning member. The following description will focus on the differences from the first embodiment. As described in the first embodiment, it is possible to efficiently remove small particles by the cleaning members 12b and 13b, in which the skin layer is not formed on the contact surface with the substrate S. Therefore, in the present embodiment as well, in step S3 of FIG. 5, when cleaning with cleaning members 12b and 13b, it is mainly assumed to use the cleaning liquid containing nano bubbles.

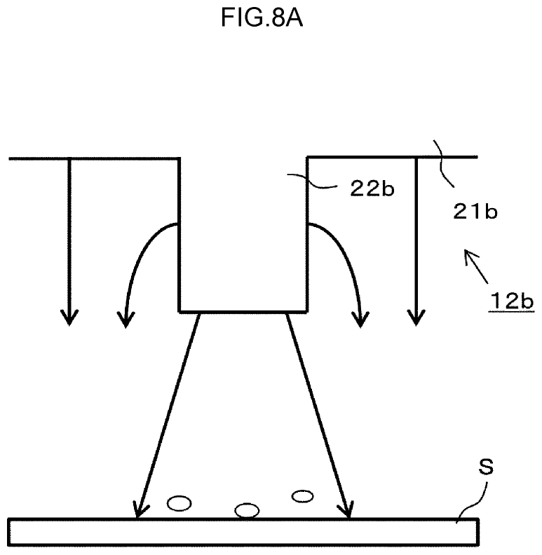

FIG. 7 is a diagram showing a schematic configuration of a cleaning liquid supplying unit 30 that supplies the cleaning liquid to the inside of the cleaning member 12b. The cleaning liquid supplying unit 30 includes a cleaning liquid supply source 31, a gas dissolver 32, a filter 33, and a supplying line 34.

The cleaning liquid supply source 31 is connected to the supplying line 34 and supplies degassed cleaning liquid to the supplying line 34. The cleaning liquid may be pure water or a chemical liquid.

The gas dissolver 32 dissolves gas in the cleaning liquid flowing through the supply line 34. As a specific example, the gas dissolver 32 dissolves the gas in the cleaning liquid by pressurizing the gas against the cleaning liquid via a membrane. In order to make the cleaning liquid contain a large amount of effective nanobubbles, it is desirable to make the cleaning liquid contain the gas up to a supersaturated state. The amount of gas dissolved can be adjusted according to the pressure and/or the flow rate of the cleaning liquid. The gas may be nitrogen gas, carbonic acid gas, hydrogen gas, and nitrogen gas is particularly effective for producing small bubbles.

Note that, it is desirable that gas dissolver 32 dissolves gas so as not to generate large bubbles in the cleaning liquid. This is because, as described later, if large bubbles are included in the cleaning liquid supplied to the substrate S, cleaning efficiency owing to the nano bubbles may decreases. However, it is difficult to prevent the bubble from occurring at all, and when the supply line 34 is bent, bubbles may occur at the bent place. Therefore, it is desirable to install filter 33.

The filter 33 is provided on the supply line 34 downstream of the gas dissolver 32, preferably as close as possible to the cleaning member 12b. The filter 33 has a mesh structure and removes large bubbles generated in the cleaning liquid. By providing the filter 33, cleaning liquid that does not contain bubbles of a certain size or more is supplied to cleaning members 12b and 13b.

The supply line 34 is composed of one or a plurality of pipes, and the cleaning member 12b is attached to the tip (the side opposite to the cleaning liquid supply source 31). Specifically, the center of the cleaning member 12b is a hollow, into which the supply line 34 is fitted, thereby communicating. And, a plurality of holes are formed in the vicinity of the tip of the supplying line 34, so that the cleaning liquid in the supplying line 34 can flow out into the cleaning member 12b. To be precise, the core member is inserted into the hollow of the cleaning member 12b and the inside of the core member is also hollow, and the supply line 34 is connected to the core member. A hole connecting the inside hollow and an outer surface is formed. The core member also acts as a role maintaining the shape of the cleaning member 12b.

Although only cleaning member 12b is drawn in FIG. 6, the supply line 34 may be branched to supply the cleaning liquid to both of the cleaning members 12b and 13b. Alternatively, liquid supply unit 30 may be provided to each of the cleaning member 12b and 13b.

In the cleaning liquid supply unit 30 as described above, the cleaning liquid is supplied from the cleaning liquid supply source 31, thereby the supply line 34 is filled with the cleaning liquid. Especially, in the downstream side of the filter 33, gas is dissolved and a large bubble is not present. Such cleaning liquid is discharged from the hole at the tip of the supplying line 34 into the cleaning member 12b. While the cleaning liquid is filled in the supplying line 34, the inside of the cleaning member 12b is porous such as sponge etc. Accordingly, the pressure applied to the cleaning liquid decreases by flowing out from the supply line 34, thereby the dissolved gas becomes small bubbles. The cleaning liquid containing such-small bubbles reaches the substrate S.

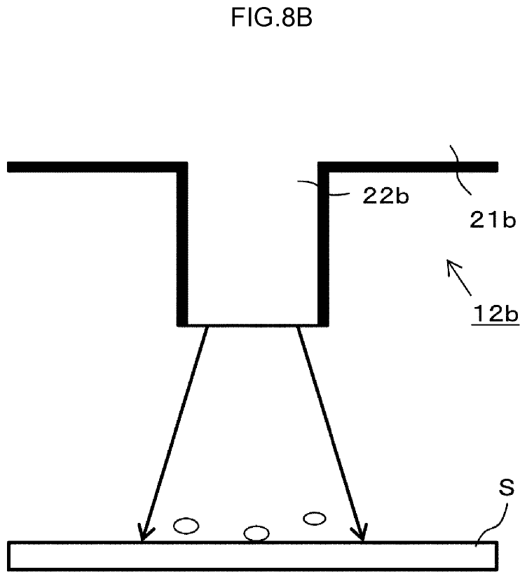

FIGS. 8A and 8B are schematic diagrams showing how the cleaning liquid reaches the substrate S from the cleaning member 12b.

In FIG. 8A, no the skin layer is provided not only on the tip surface of the nodule portion 22b, but also on the side surface of the nodule portion 22b and the surface of the roll body 21b. In this case, the cleaning liquid is mainly discharged from the tip surface of the nodule portion 22b. However, the cleaning liquid is also discharged from the side surface of the nodule portion 22b and the surface of the roll body 21b.

On the other hand, in FIG. 8B, no skin layer is provided on the tip surface of the nodule portion 22b, but a skin layer is provided on the side surface of the nodule portion 22b and on the surface of the roll body 21b. In this case, it is relatively difficult for the cleaning liquid to penetrate the skin layer on the side surface and the surface of the roll body 21b, and thus the cleaning liquid is supplied preferentially to the front surface of the nodule portion 22b (that is, the contact surface with the substrate S) to the surface of the substrate S. Therefore, in the present embodiment, as shown in FIG. 8B, it is desirable that no skin layer is provided only on the tip surface of the nodule part 22b.

In order to remove small particles adhering to the substrate S, it is desirable that the diameter of the bubble contained in the cleaning liquid is less than 100 nm, and it is desirable that the bubble with a size larger than that is not contained in the cleaning liquid. This is because, existence of a large bubble may disturb small bubbles to contact the substrate S, and effect of the cleaning efficiency improvement owing to the nano bubbles may be reduced. In order for bubbles whose size is equal to or larger than 100 nm not to be contained in the cleaning liquid reaching the substrate S, it is preferable to adjust the amount of gas dissolved by the gas dissolver 32, or appropriately adjust the mesh size of the filter 33.

In this way, small particles can be removed more effectively by cleaning with cleaning members 12b and 13b while supplying cleaning liquid containing nano bubbles onto the substrate S. Furthermore, by providing cleaning liquid from cleaning liquid supplying unit 30, it can also be used as inner rinse for cleaning members 12b and 13b.

For example, when starting up the cleaning members 12b and 13b for the first use, the cleaning liquid from the cleaning liquid supplying unit 30 can be used as the inner rinse. In a case where the cleaning members 12b and 13b are made of resin such as PVA, the raw materials may remain due to insufficient reaction when producing it by reacting the raw materials. Therefore, it is necessary to remove the remaining raw materials when starting up cleaning members 12b and 13b. In the present embodiment, by supplying the cleaning liquid containing nano bubbles from the cleaning liquid supplying unit 30 to the insides of the cleaning members 12b and 13b, the remaining raw materials can be efficiently removed from the cleaning members 12b and 13 in a short time. The starting up may be performed by cleaning a dummy substrate in the same manner as a normal substrate with the new cleaning members 12b and 13b being attached to the substrate cleaning device, for example (supplying it as inner rinse). Alternatively, the new cleaning members 12b and 13b may be pressed against a plate material such as quartz without using the dummy substrate. Alternatively, the starting up may be performed by supplying the cleaning liquid from the cleaning liquid supplying unit 30 to the inside of the cleaning members 12b and 13b without pressing the cleaning members 12b and 13b onto the object.

As another example, the cleaning liquid from the cleaning liquid supplying unit 30 can be used as inner rinse for self-cleaning of the cleaning members 12b, 13b. When cleaning the substrate S with the cleaning members 12b, 13b, the particles removed from the substrate S may get into the surface or inside of the cleaning members 12b and 13b. Therefore, after completing the cleaning of some substrates and before starting cleaning of another substrate, a step of removing particles which have entered the cleaning members 12b and 13b (self-cleaning of the cleaning members 12b and 13b) is needed. In the present embodiment, by supplying the cleaning liquid containing nano bubbles from the cleaning liquid supplying unit 30 to the inside of the cleaning members 12b and 13b to discharge it from the surface, the particles that have entered inside of the cleaning members 12b and 13b can be removed efficiently. In particular, since the cleaning liquid supplied to the inside of the cleaning members 12b and 13b is discharged to the outside from the nodule part 22b, it is possible to clean the nodule part 22b that comes in contact with the substrate S. The self-cleaning of the cleaning member 12b and 13b may be performed by pressing the cleaning members 12b and 13b against a plate material such as quartz while supplying as inner rinse, or performed by supplying the cleaning liquid from the cleaning liquid supplying unit 30 into the inside of the cleaning members 12b, 13b without pressing the cleaning members 12b, 13b against the object. Usually, when the self-cleaning is performed by pressing the cleaning members 12b and 13b against the plate material and so on, the plate material may be contaminated. On the other hand, according to the present method also can clean the plate material itself, which is so effective.

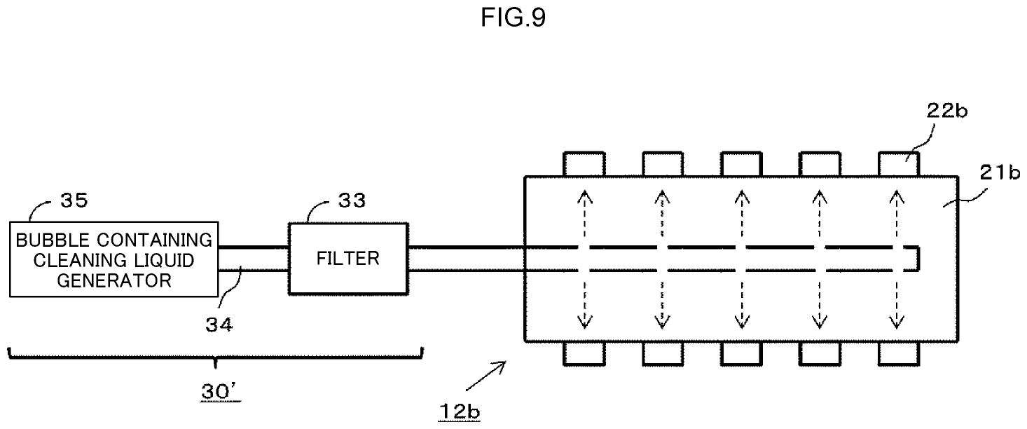

FIG. 9 is a diagram showing a schematic configuration of a cleaning liquid supplying unit 30′ which is a modified example of FIG. 7. Different from the cleaning liquid supplying unit 30 of FIG. 7, the cleaning liquid supplying unit 30′ of FIG. 9 has a bubble containing cleaning liquid generator 35. The bubble containing cleaning liquid generator 35 generates cleaning liquid containing bubbles and supplies it to the supplying line 34. Even with such a configuration, the substrate S can be cleaned with the cleaning liquid containing nano bubbles.

As described above, in the second embodiment, cleaning of the substrate S is performed by supplying the cleaning liquid in which gas is dissolved to the cleaning members 12b and 13b and using the cleaning liquid containing nano bubbles. Therefore, the cleaning efficiency is improved. Further, by using the cleaning liquid as inner rinse to the cleaning members 12b and 13b, it is possible to shorten the startup time and clean cleaning members 12b and 13b.

Note that, such a cleaning liquid supplying unit 30 may be provided on only one of the cleaning members 12b and 13b, or may be provided on the cleaning member 12a and/or the cleaning member 13a.

The cleaning method described above can also be applied to various substrate cleaning device. Hereinafter, some modified examples of the substrate cleaning device will be explained (the explanation common to FIG. 2 will be omitted as appropriate).

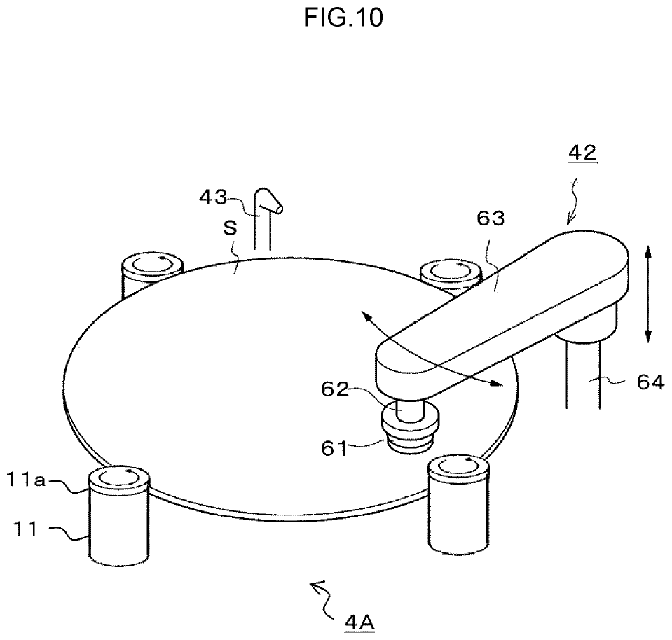

FIG. 10 is a perspective view showing a schematic configuration of another substrate cleaning device 4A. This substrate cleaning device 4A includes spindles 11, a cleaning mechanism 42, and one or more nozzles 43.

The cleaning mechanism 42 consists of a cleaning member 61, a rotating shaft 62, a swing arm 63, a swing shaft 64, and so on.

The cleaning member 61 is, for example, a pencil type cleaning tool made of PVA, the lower surface of which is a cleaning surface, and the upper surface of which is fixed to the lower end of the rotating shaft 62. When substituting the substrate cleaning device 4A shown in FIG. 10 for the substrate cleaning device 4a, a skin layer is formed on the contact surface of the cleaning member 61 with the substrate. On the other hand, when substituting substrate cleaning device 4A shown in FIG. 10 for the substrate cleaning device 4b, no skin layer is formed on the contact surface of the cleaning member 61 with the substrate.

The rotating shaft 62 extends perpendicular to a face of the substrate S (that is, vertically) , and the cleaning member 61 is rotated in the horizontal plane by the rotation of the rotating shaft 62.

The swing arm 63 extends horizontally, one end of which is connected to the upper end of the rotating shaft 62, and the other end of which is connected to the swing shaft 64. The swing shaft 64 is provided with a motor (not shown).

The swing shaft 64 extends perpendicular to the face of the substrate S (that is, vertically), and can move up and down. When the swing shaft 64 moves downward, the lower surface of the cleaning member 61 contacts the surface of the substrate S. When the swing shaft 64 moves upward, the lower surface of the cleaning member 61 separates from the surface of the substrate S. Further, the rotation of the swing shaft 64 swings the swing arm 63 in the horizontal plane.

It should be noted that instead of moving the cleaning member 61 in an arc around the swing shaft 64, the cleaning member 61 may be moved in a straight line. Further, although not shown in the figure, as described in the second embodiment, cleaning liquid containing dissolved gas may be supplied to inside of the cleaning member 61.

Up to now, though embodiments in which the substrate is cleaned while rotating it in a horizontal state is described, the present invention can be applied to embodiments in which the substrate is in a vertical or oblique state. Further, the substrate does not always have to be rotated.

Further, as the cleaning member 61, the present invention can be applied to buff cleaning for performing contact cleaning with stronger physical power such as hard pad or soft pad.

The above-described embodiments are described for the purpose of enabling a person ordinary skilled in the art in the technical field to which the present invention belongs to implement the present invention. Various modifications of the above-described embodiments will be understood by those skilled in the art. It goes without saying that the technical idea of the present invention can be applied to other embodiments. Therefore, the present invention is not limited to the described embodiments, It should be the widest range according to the technical idea defined by the range.

### EXPLANATION OF REFERENCE SINGS

4a,4b substrate cleaning device
11 spindle
12a,12b,13a,13b cleaning member
14,15 cleaning liquid supply nozzle
21a,21b roll body
22a,22b nodule part
30 cleaning liquid supplying unit
31 cleaning liquid supply source
32 gas dissolver
33 filter
34 supplying line
35 bubble containing cleaning liquid generator

1. A substrate processing apparatus comprising:
a first cleaning member configured to clean a substrate by a contact face on which a skin layer is provided; and
a second cleaning member configured to clean the substrate after cleaned by the first cleaning member, by a contact face on which a skin layer is not provided.

2. The substrate processing apparatus according to claim 1, further comprising a cleaning liquid supplying unit configured to supply a cleaning liquid in which gas is dissolved to an inside of the second cleaning member,
wherein the cleaning liquid supplied to the inside of the second cleaning member reaches the substrate from a surface of the second cleaning member.

3. The substrate processing apparatus according to claim 2, wherein the cleaning liquid supplying unit comprises:
a supplying line connected to the inside of the second cleaning member;
a gas dissolver configured to dissolve the gas to the cleaning liquid; and
a filter provided between the gas dissolver and the second cleaning member on the supplying line.

4. The substrate processing apparatus according to claim 2, wherein the cleaning liquid supplying unit comprising:
a supplying line connected to the inside of the second cleaning member;
a bubble containing cleaning liquid generator configured to generate bubble-dissolved cleaning liquid; and
a filter provided between the bubble containing cleaning liquid generator and the second cleaning member on the supplying line.

5. The substrate processing apparatus according to claim 2, wherein the cleaning liquid reaching the substrate contains a bubble.

6. The substrate processing apparatus according to claim 5, wherein the cleaning liquid reaching the substrate contains the bubble whose diameter is less than 100 nm.

7. The substrate processing apparatus according to claim 6, wherein the cleaning liquid reaching the substrate does not contain the bubble whose diameter is equal to or more than 100 nm.

8. A substrate cleaning method comprising:
a first cleaning step configured to clean a substrate by a contact face of a first cleaning member, a skin layer being provided on the contact face; and
a second cleaning step after the first cleaning step configured to clean the substrate by a contact face of a second cleaning member, a skin layer not being provided on the contact face.

9. The substrate cleaning method according to claim 8, wherein the second cleaning step comprises:
supplying cleaning liquid containing a bubble whose diameter is less than 100 nm to an inside of the second cleaning member, and performing cleaning by the second cleaning member while causing the cleaning liquid to reach the substrate from a surface of the second cleaning member.

10. The substrate cleaning method according to claim 8, further comprising a step configured to, before the second cleaning member is firstly used, supply a bubble whose diameter is less than 100 nm to an inside of the second cleaning member to discharge the cleaning liquid from a surface of the second cleaning member.

11. The substrate cleaning method according to claim 8, further comprising a step configured to, after completing one substrate and before starting cleaning another substrate, supply a bubble whose diameter is less than 100 nm to an inside of the second cleaning member to discharge the cleaning liquid from a surface of the second cleaning member.
